(19) United States
(12) Patent Application Publication
(10) Pub. No.: US 2024/0371597 A1
(43) Pub. Date: Nov. 7, 2024

(54) MULTIPOLE ELEMENT, IMAGE ERROR CORRECTOR AND PARTICLE BEAM SYSTEM

(71) Applicant: Carl Zeiss Microscopy GmbH, Jena (DE)

(72) Inventors: Dirk Preikszas, Oberkochen (DE); Juergen Pommerenke, Heidenheim (DE)

(21) Appl. No.: 18/654,627

(22) Filed: May 3, 2024

(30) Foreign Application Priority Data
May 3, 2023 (DE) 10 2023 111 471.9

(51) Int. Cl. H01J 37/153; H01J 37/141

(52) U.S. Cl. CPC H01J 37/153; H01J 37/141; H01J 2237/141; H01J 2237/153

(57) ABSTRACT

A multipole element for creating a magnetic multipole field or for creating an electric-magnetic multipole field for a particle beam system such as a scanning electron microscope, for example, comprises: a tube surrounding a central axis of the multipole element; an external space assembly arranged outside of the tube and a vacuum space assembly arranged within the tube. The external space assembly comprises: a magnetically conductive circumferential pole piece surrounding the tube; a plurality of magnetically conductive supports arranged so as to be distributed around the central axis and extending from the circumferential pole piece up to an outer wall surface of the tube; and a plurality of coils. The vacuum space assembly comprises a plurality of magnetically conductive pole pieces arranged so as to be distributed around the central axis and extending from the tube in the direction of the central axis.

### CROSS-REFERENCE TO RELATED APPLICATION

This application claims benefit under 35 U.S.C. § 119 to German Application No. 10 2023 111 471.9, filed May 3, 2023. The entire disclosure of this application is incorporated by reference herein.

### FIELD

The present disclosure relates to a multipole element, an image error corrector having the multipole element and a particle beam system having the multipole element. The disclosure also relates to a multipole element for creating a magnetic multipole field or for creating an electric-magnetic multipole field for a particle beam system such as a scanning electron microscope, for example.

### BACKGROUND

Particle beam systems denote systems in which a beam of electrically charged particles (for example electrons or ions) is created and directed at a sample in order to analyse the sample or process the sample. To this end, the particle beam can be raster-scanned over the sample. In the case of an electron beam microscope, interaction products (such as backscattered electrons, secondary electrons, electromagnetic radiation, light, etc.) created by the interaction of the electron beam with the sample are detected in order to analyse the sample. In the case of an ion beam processing device, the ion beam is directed at the sample in order to process the sample, for example remove material from the sample or deposit material on the sample.

In such particle beam systems, multipole elements are used to manipulate or deflect the particle beam. Examples of conventional multipole elements include stigmators and aberration correctors.

In multipole elements for creating a magnetic multipole field, the magnetic multipole field is created by coils. The coils are formed by a multiplicity of turns of an insulated wire line. The insulation of the wire line outgasses during operation. The particle beam is guided in a vacuum region and the outgassing of the insulation of the wire line in the vacuum region impairs a vacuum created in the vacuum region during the operation of the multipole element. Encapsulations for the coils in the vacuum region are complicated and expensive. It can therefore be desirable to arrange the coils outside of the vacuum region.

However, if coils are arranged outside of the vacuum region, magnetic fluxes created by the coils are guided into the vacuum region so that a magnetic multipole field created by the magnetic fluxes can act on the particle beam. EP 0 379 690 A1 discloses a multipole element in which pole pieces pass through a separating wall of the vacuum region and are sealed off by vacuum seals. However, with this configuration, sealing the pole pieces can be complicated and the pole pieces may be provided with an electrical (and hence also magnetic) insulation elsewhere if the magnetic multipole element should be enhanced to form an electric-magnetic multipole element.

### SUMMARY

In an aspect, the disclosure provides a multipole element comprising: a tube surrounding a central axis of the multipole element; an external space assembly arranged outside of the tube in relation to a radial direction emanating perpendicularly from the central axis; and a vacuum space assembly arranged within the tube in relation to the radial direction. The external space assembly comprises: a magnetically conductive circumferential pole piece surrounding the tube in a circumferential direction, the circumferential direction being oriented perpendicularly to the central axis and to the radial direction; a plurality of magnetically conductive supports arranged so as to be distributed around the central axis and extending from the circumferential pole piece against the radial direction up to an outer wall surface of the tube; and a plurality of coils. The vacuum space assembly comprises: a plurality of magnetically conductive pole pieces arranged so as to be distributed around the central axis and extending from the tube against the radial direction.

The coils of the multipole element are arranged in an external space which is situated outside of the tube in the radial direction. During operation, a vacuum within which for example a particle beam propagates is created in a vacuum region situated within the tube in the radial direction. Since the coils are arranged in the external space, in general, an outgassing by the coils does not influence the vacuum in the vacuum region.

Magnetic fluxes which flow through the tube and further through the pole pieces are excited in the circumferential pole piece and the supports by the coils. The magnetic flux emerges from the pole pieces at gaps between the pole pieces and forms a magnetic multipole field in the process. Neither the pole pieces nor the supports pass through the tube in the radial direction. Thus, there is no need to use vacuum seals in order to guide the magnetic fluxes excited in the external space into the vacuum region for the purpose of creating the magnetic multipole field. If the tube moreover is electrically nonconductive, then the pole pieces of the vacuum assembly can easily be placed at different, high electric potentials.

The multipole element can be used in diverse particle beam devices. For example, the multipole element can be used in an electron beam device such as an electron beam microscope or in an ion beam device such as an ion beam processing device.

Further aspects of the disclosure are an image error corrector comprising at least one multipole element of the type described herein, and a particle beam system comprising at least one image error corrector of the type described herein.

### BRIEF DESCRIPTION OF THE FIGURES

Embodiments of the disclosure are explained in detail below with reference to figures. In detail:

FIG. 1 shows a schematic cross-sectional view of a multipole element;

FIG. 2 shows a perspective sectional view of the multipole element;

FIG. 3 shows a schematic cross-sectional view of a first example of a pole piece of the multipole element;

FIG. 4 shows a schematic cross-sectional view of a second example of a pole piece of the multipole element;

FIG. 5 shows a schematic illustration serving to explain the shape of pole pieces;

FIG. 6 shows a schematic cross-sectional view of a third example of a pole piece of the multipole element;

FIG. 7 shows a schematic cross-sectional view of a fourth example of a pole piece of the multipole element;

FIG. 8 shows a schematic illustration of an octupole winding of the multipole element;

FIG. 9 shows a schematic illustration of quadrupole windings of the multipole element;

FIG. 10 shows a schematic illustration of dipole windings of the multipole element;

FIG. 11 shows a schematic cross-sectional view of a further multipole element;

FIG. 12 shows a schematic illustration of a particle beam system; and

FIG. 13 shows a schematic cross-sectional view at a connecting point between a beam tube and a multipole element.

### DETAILED DESCRIPTION

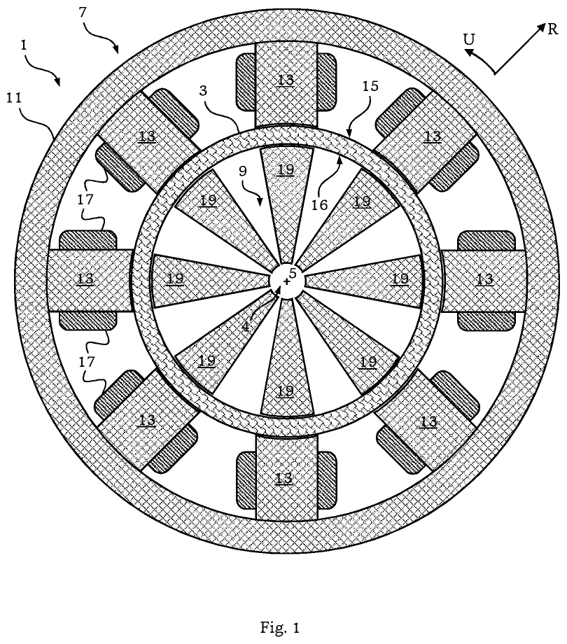

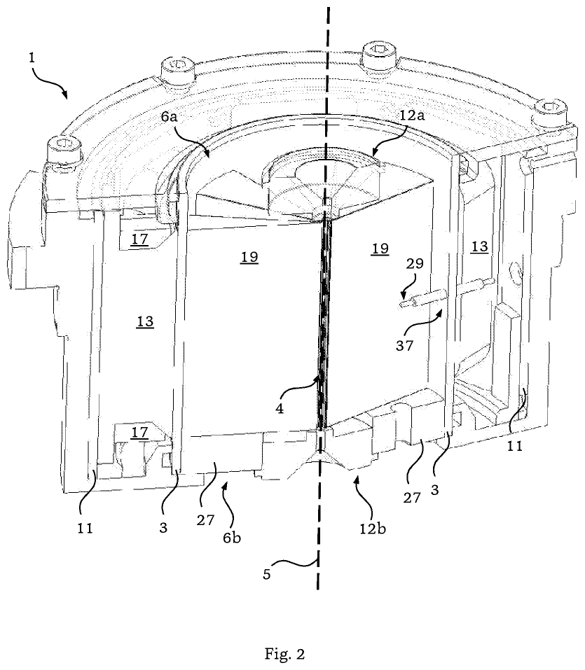

A multipole element according to an embodiment of the disclosure is described below with reference to FIGS. 1 and 2. The multipole element 1 is a magnetic multipole element. This means that the multipole element is configured to create a magnetic multipole field. In the process, equal numbers of magnetic north poles and magnetic south poles are created.

The geometry of the multipole element 1 is described via a cylindrical coordinate system defined by a longitudinal direction, a radial direction R and a circumferential direction U. To simplify the description, the assumption is made that the longitudinal direction coincides with a central axis 5 of the multipole element 1. The radial direction R is perpendicular to the longitudinal direction (central axis 5). The radial direction R emanates perpendicularly from the central axis 5 and extends away from the central axis 5. The circumferential direction U is always perpendicular to the longitudinal direction and to the radial direction R and parameterized by an angle of rotation about the longitudinal direction.

FIG. 1 shows a schematic cross-sectional view of the multipole element 1 in a cross-sectional plane oriented perpendicular to the central axis 5. In FIG. 1, the central axis 5 and the longitudinal direction are represented by a cross at the centre of the multipole element 1. The central axis 5 and the longitudinal direction extend perpendicular to the plane of the drawing in FIG. 1. FIG. 2 shows a perspective sectional view of the multipole element 1, the section being in a plane spanned by the central axis 5 and the radial direction R.

The multipole element 1 comprises a tube 3 surrounding the central axis 5 of the multipole element 1. The multipole element 1 is substantially symmetrical about the central axis 5. The tube 3 has an upper opening 6a at a longitudinally upper end of the tube 3 and has a lower opening 6b at a longitudinally lower end of the tube 3. The tube 3 consists of a wall which circumferentially encloses the central axis 5 at a distance from the central axis 5 and which is longitudinally elongate. A spatial region located within the tube 3 and completely enclosed by the upper opening 6a, the lower opening 6b and a radially inner wall surface 16 of the tube 3 is referred to as vacuum space. A vacuum is created in the vacuum space during operation. A spatial region located outside of the tube 3 and delimited by the upper opening 6a, the lower opening 6b and a radially outer wall surface 15 of the tube 3 is referred to as external space. Ambient pressure (no vacuum) is prevalent in the external space during operation.

The multipole element 1 also comprises an external space assembly 7 arranged outside of the tube 3 in relation to the radial direction R and a vacuum space assembly 9 arranged within the tube 3 in relation to the radial direction R. Accordingly, the external space assembly 7 is situated in the external space, and the vacuum space assembly 9 is situated in the vacuum space. This means that all elements of the external space assembly 7 are arranged outside of the tube 3 in relation to the radial direction R and that all elements of the vacuum space assembly 9 are arranged within the tube 3 in relation to the radial direction R. The tube 3 provides a vacuum separation in the radial direction R between the vacuum space assembly 9 and the external space assembly 7. This means that a vacuum created vis-à-vis the external space in the vacuum space is maintained by the tube 3 in relation to the radial direction R. When the multipole element 1 is used in a particle beam system, the upper end of the tube 3 and the lower end of the tube 3 are connected to other components of the particle beam system, whereby the vacuum vis-à-vis the external space is also maintained in relation to the longitudinal direction.

The external space assembly 7 comprises a circumferential pole piece 11 which surrounds the tube 3 in the circumferential direction U. This means that the circumferential pole piece 11 extends in the circumferential direction U around the tube 3 at a distance from the tube 3.

The external space assembly 7 also comprises a plurality of supports 13 arranged so as to be distributed around the central axis 5 and extending from the circumferential pole piece 11 against the radial direction R up to an outer wall surface 15 of the tube 3. This means that the supports 13 extend from the circumferential pole piece 11 to the central axis 5. The supports 13 extend up to the outer wall surface 15 of the tube 3. In this case, the supports 13 can penetrate into the tube 3 without piercing fully through the tube 3. This means that the supports 13 do not pass through the tube 3 in the radial direction R.

Each support 13 has an inner surface. The inner surface of the support 13 faces the tube 3. This means that the inner surface of the support 13 is opposite the tube 3 in the radial direction. Each support 13 has an outer surface. The outer surface of the support 13 faces the circumferential pole piece 11. This means that the outer surface of the support 13 is opposite the circumferential pole piece 11 in the radial direction. Alternatively, the circumferential pole piece 11 and the supports 13 are manufactured from one piece.

The external space assembly 7 also comprises a plurality of coils 17. The coils can be carried by the circumferential pole piece 11 and/or by the supports 13. Each support 13 is assigned one of the coils 17.

The vacuum space assembly 9 comprises pole pieces 19 which are arranged so as to be distributed around the central axis 5 and extend from the tube 3 against the radial direction R. This means that the pole pieces 19 extend to the central axis 5 starting from the inner wall surface 16 of the tube 3. The pole pieces 19 extend up to the inner wall surface 16 of the tube 3. In this case, the pole pieces 19 can penetrate into the tube 3 without piercing fully through the tube 3. The pole pieces 19 are not in contact with the supports 13. This means that the pole pieces 19 do not pass through the tube 3 in the radial direction R.

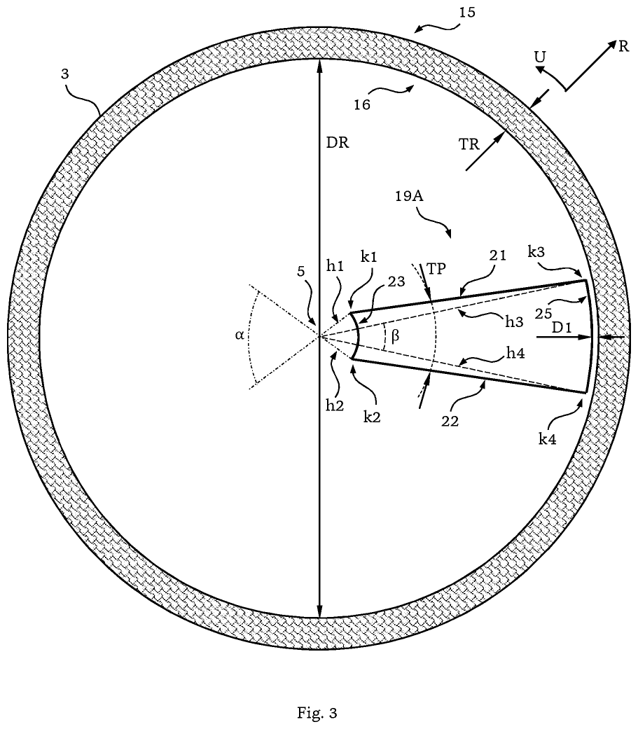

Each pole piece 19 has an inner surface 23 (see FIG. 3). The inner surface 23 faces the central axis 5. Each pole piece 19 has an outer surface 25. The outer surface 25 faces the tube 3. This means that the outer surface 25 is opposite the tube 3 in the radial direction.

Each pole piece 19 has an upper surface. The upper surface faces the upper opening 6a in the tube 3. Each pole piece 19 has a lower surface. The lower surface faces the lower opening 6b in the tube 3. Each pole piece 19 has a first lateral surface 21 and a second lateral surface 22. The first lateral surface 21 faces a first different adjacent pole piece in the circumferential direction U. The second lateral surface 22 faces a second different adjacent pole piece against the circumferential direction U. In the example shown in FIG. 1, the inner surface 23 and the outer surface 25 are circular segments centred on the central axis 5; and the lateral surfaces 21, 22 of the pole pieces 19 are plane faces. In the longitudinal direction, the pole pieces 19 are arranged between an upper termination pole piece 12a and a lower termination pole piece 12b. The termination pole pieces 12a, 12b have substantially the shape of thick-walled tubes and are magnetically conductive. Outside the multipole element, this causes the magnetic multipole field to decay quickly in the longitudinal direction.

A propagation region 4 extends along the central axis 5 over the entire length of the multipole element 1, extends over the whole circumference of the multipole element 1 in the circumferential direction U and extends from the central axis 5 to the pole pieces 19 in the radial direction R. The propagation region 4 is an empty space in which a particle beam can propagate through the multipole element 1. The magnetic multipole field is created in the propagation region 4 and thus acts on the particle beam in the propagation region 4. In particular, the propagation region 4 is delimited by the upper opening 6a in the tube 3 and the lower opening 6b in the tube 3.

The tube 3 is magnetically nonconductive. This element therefore has a high magnetic resistance. For example, the tube 3 is formed from a ceramic or a plastic. Aluminium oxide (Al2O3) is an example of a suitable ceramic. Polyether ether ketone (PEEK) is an example of a suitable plastic.

The circumferential pole piece 11, the supports 13 and the pole pieces 19 are each magnetically conductive. These elements therefore have a low magnetic resistance. As a result, magnetic fluxes created by the coils 17 can pass through these elements with little loss, and hence a magnetic multipole field can be created efficiently in the propagation region 4.

A magnetic multipole field created by the coils 17 can be created efficiently in the propagation region 4 by way of the above-described configuration of the multipole element 1. A magnetic flux excited by the coils 17 passes from the coils 17 through the circumferential pole piece 11, through the supports 13, through the tube 3, through the pole pieces 19 and via a gap between the pole pieces 19. Moreover, the coils 17 are arranged in the external space which is under normal pressure during operation. An outgassing of wire insulations of the coils 17 therefore does not impair a vacuum created in the vacuum space. Moreover, the pole pieces 19 and the supports 13 can be electrically insulated from one another.

The tube 3 can be a one-piece body. The tube 3 can consist of exactly one material. An internal diameter DR of the tube 3 measured in the radial direction R (see FIG. 3) can have a value in the range from 20 mm to 200 mm. A length of the tube 3 measured along the central axis 5 can have a value in the range from 20 mm to 200 mm. A wall thickness TR of the tube 3 measured in the radial direction R (see FIG. 3) can be greater than zero. Within the confines of acceptable stability, the wall thickness TR can be as thin as possible in order to have a magnetic resistance that is as low as possible. The wall thickness TR can be less than 20% of the internal diameter DR of the tube 3. The wall thickness TR can be less than 10% of the internal diameter DR of the tube 3. The wall thickness TR can be less than 1% of the internal diameter DR of the tube 3. In addition or in an alternative, the wall thickness TR cam be less than 5 mm. The wall thickness TR can be less than 2 mm. The wall thickness TR can be less than 1 mm.

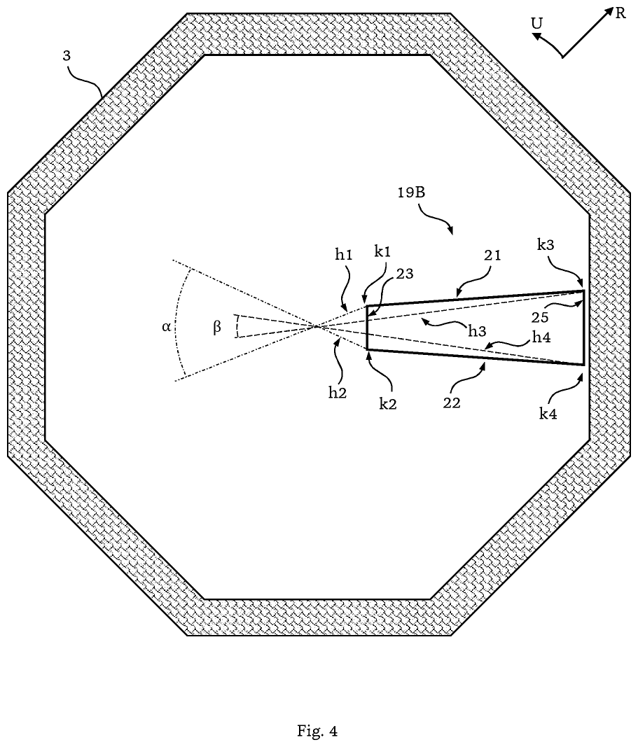

The tube 3 can have a symmetrical cross section in a sectional plane oriented perpendicular to the central axis 5. In particular, the cross section can have a shape of a circular ring with a constant internal diameter DR and a constant external diameter (see FIG. 3). In an alternative, the cross section can have a shape of an elliptic ring with an internal diameter DR that varies in the circumferential direction. In a further alternative, the cross section can have a shape of a (regular) polygon or the like. An example of a tube 3 with a cross section in the shape of an octagon is depicted in FIG. 4. In the longitudinal direction, the cross section of the tube 3 can be constant over the entire length of the tube 3.

A diameter of the propagation region 4 measured in the radial direction R can have a value in the range from 1 mm to 20 mm. For example, the diameter of the propagation region 4 is determined as the distance between inner surfaces 23 of two pole pieces 19 that are opposite one another across the central axis 5. A length of the propagation region 4 in the longitudinal direction corresponds to the length of the tube 3.

The circumferential pole piece 11 can be formed in one piece or consist of a plurality of pieces. The circumferential pole piece 11 provides a magnetic guide between supports 13 that are adjacent to one another in the circumferential direction U. To this end, the circumferential pole piece 11 for example is in planar contact with the supports 13.

The supports 13 and the circumferential pole piece 11 can be formed in one piece. In this case, the supports 13 are protrusions which project from the circumferential pole piece 11 against the radial direction R. In an alternative, the supports 13 and the circumferential pole piece 11 can be formed as separate pieces.

The supports 13 can rest against the outer wall surface 15 of the tube 3. In this case, a distance measured in the radial direction R between the supports 13 and the tube 3 is zero. In an alternative, the supports 13 can have a distance measured in the radial direction R of greater than zero from the outer wall surface 15 of the tube 3. The distance can be less than 20% of the internal diameter DR of the tube 3 measured in the radial direction R. The distance can be less than 10% of the internal diameter DR of the tube 3. The distance can be less than 1% of the internal diameter DR of the tube 3. In addition or in an alternative, the distance can be less than 5 mm. The distance can be less than 1 mm.

The distance can be less than 0.1 mm.

In particular, the supports 13 are arranged with a symmetrical distribution in the circumferential direction U. This means that a difference between angles of rotation at which any two supports 13 that are adjacent in the circumferential direction U are arranged is 360°/(number of supports).

The pole pieces 19 can rest against the inner wall surface 16 of the tube 3. In this case, a distance D1 (see FIG. 3) measured in the radial direction R between the pole pieces 19 and the tube 3 is zero. In an alternative, the pole pieces 19 can have a distance D1 measured in the radial direction R of greater than zero from the inner wall surface 16 of the tube 3. The distance D1 can be less than 20% of the internal diameter DR of the tube 3 measured in the radial direction R. The distance D1 can be less than 10% of the internal diameter DR of the tube 3. The distance D1 can be less than 1% of the internal diameter DR of the tube 3. In addition or in an alternative, the distance D1 can be less than 5 mm. The distance D1 can be less than 1 mm. The distance D1 more can be less than 0.1 mm.

In particular, the pole pieces 19 are arranged with a symmetrical distribution in the circumferential direction U. As a result, the created multipole field has a high degree of symmetry. As shown in FIG. 1, the pole pieces 19 can lie opposite one another across the central axis 5 in pairs.

In particular, the pole pieces 19 do not have recesses for mounting the pole pieces 19. In particular, the pole pieces 19 do not have holes and female threads. As a result, the magnetic resistance of the pole pieces 19 is lower and the magnetic flux through the pole pieces 19 remains undisturbed.

The number of pole pieces 19 and the number of supports 13 are generally the same but may deviate from one another in special cases. However, the number of pole pieces 19 specifies the maximum number of poles of the magnetic multipole field.

The supports 13 are arranged relative to the pole pieces 19 such that a magnetic resistance from the supports 13 through the tube 3 into the pole pieces 19 is as small as possible. For example, the supports 13 form an extension of the pole pieces 19 in the radial direction R. For example, the supports 13 are opposite the pole pieces 19 in the radial direction R.

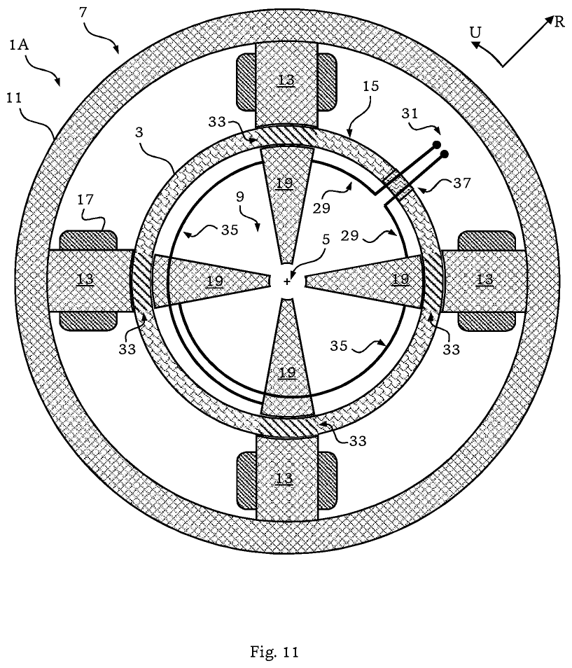

In the example shown in FIG. 1, the multipole element 1 is a magnetic octupole. This means that the multipole element 1 is configured to create a magnetic octupole field. However, the multipole element 1 is not restricted to a magnetic octupole. The multipole element 1 can be designed such that the magnetic multipole field has four poles (quadrupole element) or six poles (hexapole element) or 12 poles or 16 poles. An example of a quadrupole element is described below with reference to FIG. 11.

As shown in FIG. 2, the multipole element 1 may also comprise a mount 27 for retaining the pole pieces 19. In particular, the mount 27 is part of the vacuum space assembly 9. For example, the mount 27 comprises an upper retaining part (not depicted in FIG. 2 for improved clarity of the drawing) arranged longitudinally above the pole pieces 19 and a lower retaining part arranged longitudinally below the pole pieces 19. The upper and lower retaining part can be fastened to the tube 3 in any desired way. In this case, the tube 3 contributes to the mount 27 and consequently is a constituent part of the mount 27. In contrast to mounts known from the prior art, in the case of which the pole pieces 19 are retained by screws, threads, retaining bolts, holes and the like introduced into the mounts, the mount 27 has no negative influence on the magnetic conductivity of the pole pieces 19. Consequently, the mount 27 enables an efficient creation of the magnetic multipole field.

Alternatively, the mount 27 can also be provided entirely by the tube 3. The mount 27 can be formed by adhesively bonding, soldering or clamping the pole pieces 19 to the tube 3 or by similar processes. The mount 27 is made of a magnetically nonconductive material in order to minimize the magnetic flux from a pole piece 19 to another pole piece 19. The material of the mount 27 further is electrically conductive or nonconductive, depending on desired properties. For a purely magnetic multipole element, this means that the material of the mount 27 can be electrically conductive in order to place the electric potentials of the pole pieces 19 on a common electric potential. For an electric-magnetic multipole element, it can be electrically nonconductive in order to allow different electric potentials of the pole pieces 19.

What needs to be taken into account when designing the shape of the pole pieces 19 is that high electrical currents in the coils 17 may lead to an uncontrollably changing magnetic multipole field (so-called drifting) on account of power losses in the coils 17. A thicker wire reduces the power losses in the coils but increases their volume. However, installation space is limited, and so the coils cannot be arbitrarily large. An efficient transfer of the magnetic fluxes from the supports 13 through the tube 3 to the pole pieces 19 is therefore particularly important. The efficiency can be influenced by the shape of the pole pieces 19.

Particular configurations of the pole pieces 19 are described with reference to FIGS. 3 and 4. FIG. 3 shows a schematic cross-sectional view of a first example of a pole piece 19A of the multipole element 1 in a cross-sectional plane oriented perpendicular to the central axis 5. FIG. 4 shows a schematic cross-sectional view of a second example of a pole piece 19B of the multipole element 1 in a cross-sectional plane oriented perpendicular to the central axis 5. To simplify the explanations, FIGS. 3 and 4 each show only a single pole piece 19A and 19B, respectively, even though the multipole element 1 always comprises a plurality of pole pieces.

FIG. 3 shows the pole piece 19A with its inner surface 23, its outer surface 25, its first lateral surface 21 and its second lateral surface 22. At a first edge k1, the first lateral surface 21 of the pole piece 19A abuts the inner surface 23 of the pole piece 19A. At a second edge k2, the second lateral surface 22 of the pole piece 19A abuts the inner surface 23 of the pole piece 19A. A first half-line h1 lies in the cross-sectional plane (plane of the drawing), emanates from the central axis 5 and runs through the first edge k1. A second half-line h2 lies in the cross-sectional plane, emanates from the central axis 5 and runs through the second edge k2. An acute angle between the first half-line h1 and the second half-line h2 is referred to as inner coverage angle α. To simplify the illustration, the first half-line h1 and the second half-line h2 were extended beyond the central axis 5 and the inner coverage angle α was plotted on the extended portions.

At a third edge k3, the first lateral surface 21 of the pole piece 19A abuts the outer surface 25 of the pole piece 19A. At a fourth edge k4, the second lateral surface 22 of the pole piece 19A abuts the outer surface 25 of the pole piece 19A. A third half-line h3 lies in the cross-sectional plane, emanates from the central axis 5 and runs through the third edge k3. A fourth half-line h4 lies in the cross-sectional plane, emanates from the central axis 5 and runs through the fourth edge k4. An acute angle between the third half-line h3 and the fourth half-line h4 is referred to as outer coverage angle β.

The peculiarity of the pole piece 19A is that the inner coverage angle α and the outer coverage angle β have values that differ from one another. For example, this means that the inner coverage angle α and the outer coverage angle β differ from one another by at least 5°. In particular, the pole pieces 19 are shaped such that the inner coverage angle α is greater than the outer coverage angle β.

The inner coverage angle α influences the magnetic resistance between the inner surface 23 of the pole pieces 19 and the propagation region 4: As the inner coverage angle α increases there is a reduction in the magnetic resistance between the inner surface 23 of the pole pieces 19 and the propagation region 4. The smaller the magnetic resistance, the smaller the excitation power used to create a desired magnetic field strength of the multipole field in the propagation region 4. In other words: The efficiency of creating the magnetic multipole field is higher the smaller the magnetic resistance is between the inner surface 23 of the pole pieces 19 and the propagation region 4.

The outer coverage angle β influences the magnetic resistance between the outer surface 25 of the pole pieces 19 and the supports 13: As the outer coverage angle β increases there is a reduction in the magnetic resistance between the outer surface 25 of the pole pieces 19 and the supports 13. The smaller the magnetic resistance, the smaller the excitation power used to create a desired magnetic field strength of the multipole field in the propagation region 4. In other words: The efficiency of creating the magnetic multipole field is higher the smaller the magnetic resistance is between the outer surface 25 of the pole pieces 19 and the supports 13.

The distance between adjacent pole pieces 19 in the circumferential direction U, which is also influenced by the inner coverage angle α and the outer coverage angle β, influences the magnetic resistance between the pole pieces 19. This magnetic resistance is subordinate to the magnetic resistance present between the pole pieces 19 and the supports 13 and guides the magnetic field around the propagation region 4. Thus, the following applies: the smaller the magnetic resistance between the pole pieces 19, the greater the excitation power used to create a desired magnetic field strength of the multipole field in the propagation region 4. In other words: The efficiency of creating the magnetic multipole field is higher the greater the magnetic resistance is between adjacent pole pieces 19 in the circumferential direction U.

The inventors have recognized that a skillful choice of the inner coverage angle α and outer coverage angle β leads to a particularly efficient creation of the magnetic multipole field.

FIG. 4 shows an example of a tube 3 with an octagonal cross section. Matched thereto, the inner surface 23 and the outer surface 25 of the pole piece 19B are not circular segments but plane faces. In the pole piece 19B shown in FIG. 4, too, the inner coverage angle α and the outer coverage angle β have values that differ from one another. The inner coverage angle α is greater than the outer coverage angle β.

Examples of shapes of pole pieces are characterized on the basis of a sector width below. The sector width is defined as the ratio of 360° to the number of pole pieces 19. The sector width is 90° in the case of a quadrupole element. The sector width is 60° in the case of a hexapole element. The sector width is 45° in the case of an octupole element.

For example, the pole pieces 19 are shaped such that a difference between the inner coverage angle α and the outer coverage angle β is at least 10% of the sector width, corresponding to a difference of at least 9° in the case of a quadrupole element and corresponding to a difference of at least 4.5° in the case of an octupole element. The difference between the inner coverage angle α and the outer coverage angle β can be at least 20% of the sector width, corresponding to a difference of at least 18° in the case of a quadrupole element and corresponding to a difference of at least 9° in the case of an octupole element.

For example, the pole pieces 19 are shaped such that a ratio of the inner coverage angle α to the sector width has a value in the range of 75% to 95%, corresponding to an inner coverage angle α in the range of 67.5° to 85.5° in the case of a quadrupole element and corresponding to an inner coverage angle α in the range of approx. 34° to approx. 43° in the case of an octupole element. The ratio of the inner coverage angle α to the sector width can have a value in the range of 80% to 90%, corresponding to an inner coverage angle α in the range of 72° to 81° in the case of a quadrupole element and corresponding to an inner coverage angle α in the range of 36° to 40.5° in the case of an octupole element.

For example, the pole pieces 19 are shaped such that a ratio of the outer coverage angle β to the sector width has a value in the range of 35% to 75%, corresponding to an outer coverage angle β in the range of 31.5° to 67.5° in the case of a quadrupole element and corresponding to an outer coverage angle β in the range of approx. 16° to approx. 34° in the case of an octupole element. The ratio of the outer coverage angle β to the sector width can have a value in the range of 50% to 70%, corresponding to an outer coverage angle β in the range of 45° to 63° in the case of a quadrupole element and corresponding to an outer coverage angle β in the range of approx. 22.5° to approx. 31.5° in the case of an octupole element.

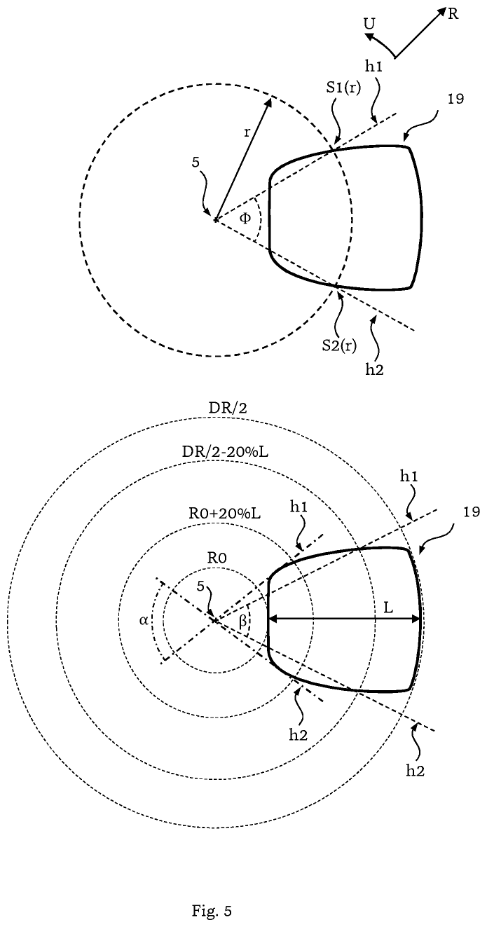

Determining the inner coverage angle α and the outer coverage angle β in accordance with the definition above may be difficult in the case of pole pieces 19 with rounded-off edges k1 to k4. Therefore, an alternative or more general definition for the inner coverage angle α and the outer coverage angle β is explained below with reference to FIG. 5.

The upper part in FIG. 5 shows an exemplary pole piece 19 with rounded-off edges, in a cross-sectional plane oriented perpendicularly to the central axis 5. The central axis 5 is perpendicular to the plane of the drawing in FIG. 5. A radius-dependent coverage angle Φ(r) specifies an acute angle between a first half-line h1 and a second half-line h2. The first half-line h1 lies in the cross-sectional plane oriented perpendicularly to the central axis 5, emanates from the central axis 5 and runs through a first point of intersection S1(r). The second half-line h2 lies in the cross-sectional plane, emanates from the central axis 5 and runs through a second point of intersection S2(r). The first point of intersection S1(r) and the second point of intersection S2(r) are (radius-dependent) points of intersection of the surface of the pole piece 19 with a circle which lies in the cross-sectional plane, has the radius r and has its centre on the central axis 5. This means that the coverage angle Φ(r) has different values depending on the radius r of the (imaginary) circle, the values depending on the specific shape of the pole piece 19.

The inner coverage angle α is intended to specify the coverage angle Φ(r) in a region in the proximity of the inner surface 23 or in the proximity of the propagation region 4. To this end, the inner coverage angle α is for example defined as follows: The inner coverage angle α is the largest radius-dependent coverage angle Φ(r) in a range R0≤r<R0+20% L, where R0 is the smallest distance measured in the radial direction R between the surface of the pole piece 19 and the central axis 5 and where L is the maximum length of the pole piece 19 measured in the radial direction R. The range R0≤r<R0+20% L denotes a range for the radius r with a lower limit at R0 and an upper limit at R0+20% L. An example of this definition is depicted in the lower part of FIG. 5, wherein the half-lines h1 and h2 have been depicted extended beyond the central axis 5 in order to improve the clarity of the figure. The half-lines h1 and h2, which define the inner coverage angle α, are depicted as dash-dotted lines. To illustrate the range R0≤r<R0+20% L, FIG. 5 depicts a circle with radius R0 around the central axis 5 and a circle with radius R0+20% L around the central axis 5.

The outer coverage angle α is intended to specify the coverage angle Φ(r) in a region in the proximity of the outer surface 25 or in the proximity of the tube 3. To this end, the outer coverage angle β is for example defined as follows: The outer coverage angle is the largest radius-dependent coverage angle Φ(r) in a range DR/2−20% L<r≤DR/2, where DR is the internal diameter of the tube 3 and where L is the maximum length of the pole piece 19 measured in the radial direction R. The range DR/2−20% L<r≤DR/2 denotes a range for the radius r with a lower limit at DR/2−20% L and an upper limit at DR/2. An example of this definition is depicted in the lower part of FIG. 5. The half-lines h1 and h2, which define the outer coverage angle β, are depicted as dashed lines. To illustrate the range DR/2−20% L<r≤DR/2, FIG. 5 depicts a circle with radius DR/2−20% L around the central axis 5 and a circle with radius DR/2 around the central axis 5.

The aforementioned values and value ranges for the inner coverage angle α and the outer coverage angle β apply in particular to pole pieces 19 whose lateral surfaces 21, 22 are plane faces. However, the aforementioned values and value ranges for the inner coverage angle α and the outer coverage angle β may also apply to pole pieces 19 whose lateral surfaces 21, 22 are curved or bent.

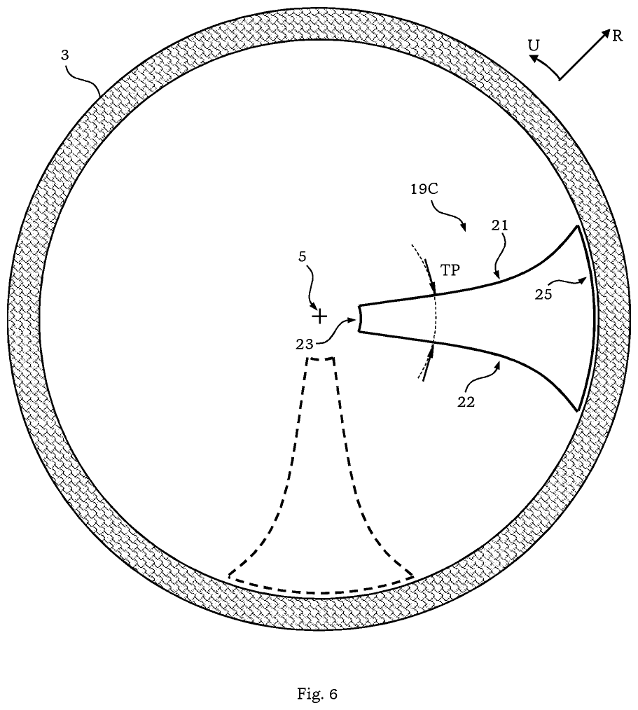

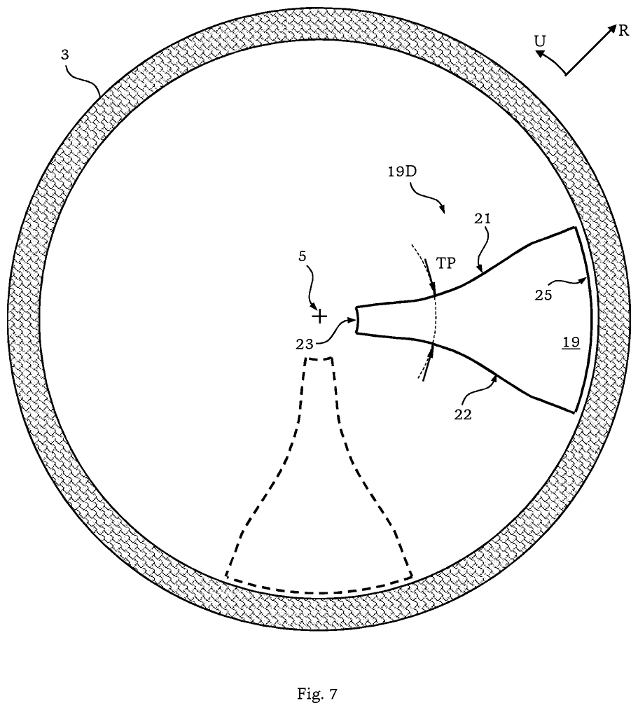

Further particular configurations of the pole pieces 19 are described with reference to FIGS. 6 and 7. FIG. 6 shows a schematic cross-sectional view of a third example of a pole piece 19C of the multipole element 1 in a cross-sectional plane oriented perpendicular to the central axis 5. FIG. 7 shows a schematic cross-sectional view of a fourth example of a pole piece 19D of the multipole element 1 in a cross-sectional plane oriented perpendicular to the central axis 5. To simplify the explanations, FIGS. 6 and 7 each show only a single pole piece 19C and 19D, respectively, (and a pole piece adjacent thereto in the circumferential direction U is indicated using dashed lines) even though the multipole element 1 always comprises a plurality of pole pieces.

The pole piece 19C is distinguished in that the two lateral surfaces 21, 22 of the pole piece 19C are not plane faces. Instead, the two lateral surfaces 21, 22 of the pole piece 19C are curved. Rather than having a curved shape, the lateral surfaces 21, 22 can also be bent.

On account of this shape of the lateral surfaces 21, 22 of the pole pieces 19, a distance over large regions of the lateral surfaces 21, 22 is greater between pole pieces 19 that are adjacent in the circumferential direction U than in the case of lateral surfaces 21, 22 with a plane face shape. As a result, the local magnetic resistance of a space between adjacent pole pieces with curved or bent lateral surfaces is greater than the local magnetic resistance of a space between adjacent pole pieces which have lateral surfaces in the form of plane faces. In comparison with pole pieces with lateral surfaces in the form of plane faces, a smaller portion of a magnetic flux guided in the pole piece emerges via the lateral surfaces 21, 22 between pole pieces with curved or bent lateral surfaces as a result. This increases the portion of the magnetic flux which is guided in the pole piece and emerges via the inner surface 23, leading to a stronger magnetic multipole field in the case of the same excitation (current through the coils 17). Hence, the efficiency of creating the magnetic multipole field is increased by the curved or bent side faces 21, 22 of the pole pieces 19.

A measure for this efficiency is the curve of a coverage angle Φ(r) as a function of radius r. For this purpose, a mid coverage angle γ is for example defined as follows: The mid coverage angle is the smallest radius-dependent coverage angle Φ(r) in a range R0+20% L<r<DR/2−20% L, where R0 is the smallest distance measured in the radial direction R between the surface of the pole piece 19 and the central axis 5, where DR is the internal diameter of the tube 3 and where L is the maximum length of the pole piece 19 measured in the radial direction R. The range R0+20% L<r<DR/2−20% L denotes a range for the radius r with a lower limit at R0+20% L and an upper limit at DR/2−20% L.

A significant increase in the efficiency of the creation of the magnetic multipole field by curved or bent side faces arises if the mid coverage angle γ is both smaller than the inner coverage angle α and smaller than the outer coverage angle β. In this context, the outer coverage angle β may also assume values greater than 75% of the sector width. In this case, the inner coverage angle α and outer coverage angle β may have different values or the same value.

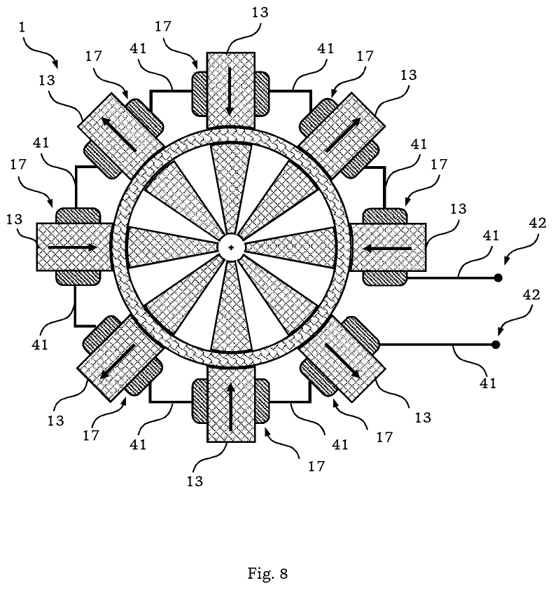

Details regarding the coils 17 of the multipole element 1 are described below with reference to FIGS. 8 to 10. Each coil 17 may comprise one or more windings. Each winding consists of at least one turn. A turn is a wire loop. Normally each winding consists of a multiplicity of turns. The number of turns per winding is typically several tens to several thousands of turns. Increasing the number of turns reduces a current used to flow through the winding in order to create a certain magnetic flux.

If a coil 17 comprises a plurality of windings, then the plurality of windings are arranged such that the magnetic fluxes created by the plurality of windings are superimposed in space. A plurality of windings are electrically insulated from one another and operated by separate current sources. A winding may extend over a plurality of the coils 17.

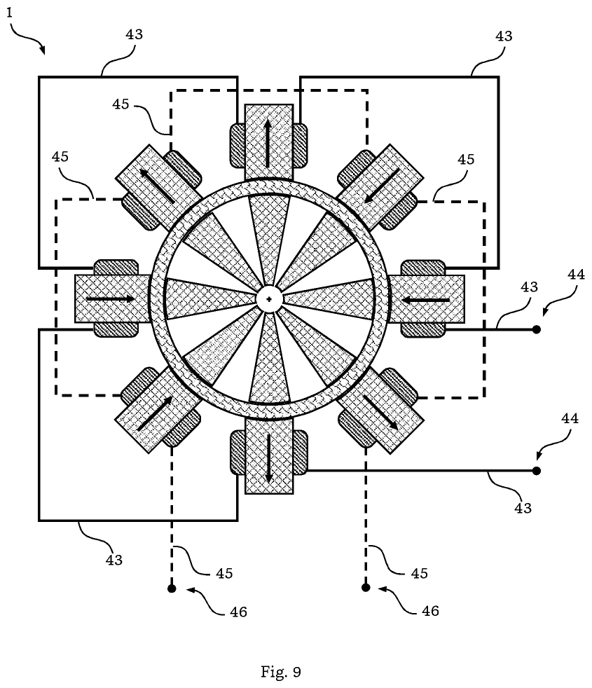

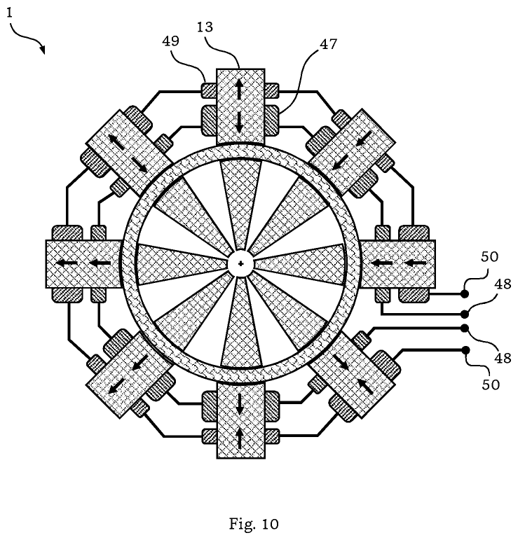

FIG. 8 shows a schematic illustration of an octupole winding 41 of the multipole element 1. The circumferential pole piece 11 is not depicted here (and not in FIGS. 9 and 10 either) for the sake of clarity. The octupole winding 41 comprises two connectors 42, at which the octupole winding 41 is connectable to a current source. The octupole winding 41 consists of a single electrical conductor (for example a wire or a bundle of wires). The electrical conductor of the octupole winding 41 extends over all eight coils 17 of the multipole element 1 designed as an octupole element. The number of turns of the octupole winding 41 at each coil 17 (i.e. the number of turns of the octupole winding 41 wound around each of the supports 13 or each portion of the circumferential pole piece 11) is the same and totals 200, for example. An arrow oriented either in the radial direction R or against the radial direction R is depicted in each of the supports 13. The orientation of the arrow specifies the winding sense of the turns of the octupole winding 41 at the respective coil 17. For example, the tip of the arrow specifies the position of the magnetic north pole, and the start of the arrow specifies the magnetic south pole. As depicted by the orientations of the arrows in FIG. 8, the winding senses of each pair of coils 17 adjacent to one another in the circumferential direction U are opposite to one another. Accordingly, in the circumferential direction U, the arrows are alternately oriented in the radial direction R and against the radial direction R. Using the octupole winding 41, it is possible to create a magnetic octupole field in the propagation region 4.

FIG. 9 shows a schematic illustration of quadrupole windings of the multipole element 1. A first quadrupole winding 43 is depicted by a solid line. The first quadrupole winding 43 comprises two connectors 44, at which the first quadrupole winding 43 is connectable to a current source. The first quadrupole winding 43 consists of a single electrical conductor. The electrical conductor of the first quadrupole winding 43 extends over four of the eight coils 17 of the multipole element 1 designed as an octupole element. When counting sequentially in the circumferential direction, the first quadrupole winding 43 extends over all odd coils 17 of the multipole element 1. The winding senses of each pair of coils 17 over which the first quadrupole winding 43 extends and which are adjacent in the circumferential direction U are opposite one another, as depicted by appropriate arrows in FIG. 9. The number of turns of the quadrupole winding 43 at each of the coils 17 is the same and totals 1000, for example. Using the first quadrupole winding 43, it is possible to create a first magnetic quadrupole field in the propagation region 4.

A second quadrupole winding 45 is depicted by a dashed line. The second quadrupole winding 45 comprises two connectors 46, at which the second quadrupole winding 45 is connectable to a current source. The second quadrupole winding 45 consists of a single electrical conductor. The electrical conductor of the second quadrupole winding 45 extends over four of the eight coils 17 of the multipole element 1 designed as an octupole element. When counting sequentially in the circumferential direction, the second quadrupole winding 45 extends over all even coils 17 of the multipole element 1. The winding senses of each pair of coils 17 over which the second quadrupole winding 45 extends and which are adjacent in the circumferential direction U are opposite one another, as depicted by appropriate arrows in FIG. 9. Using the second quadrupole winding 45, it is possible to create a second magnetic quadrupole field in the propagation region 4. Effectively, the first magnetic quadrupole field and the second magnetic quadrupole field yield a magnetic quadrupole field that is rotatable in the circumferential direction U.

FIG. 10 shows a schematic illustration of dipole windings of the multipole element 1. A first dipole winding 47 comprises two connectors 48; a second dipole winding 49 comprises two connectors 50. Hence the two dipole windings 47 and 49 are connectable to separate current sources. The dipole windings 47 and 49 each consist of a single electrical conductor.

The first dipole winding 47 has a multiplicity of turns at each support 13. The number of turns of the first dipole winding 47 at a respective support 13 is represented schematically by the thickness of the first dipole winding 47 at the respective support 13. The orientation of the turns of the first dipole winding 47 at a respective support 13 is represented schematically by an arrow (located to the inside in the radial direction R) at the respective support 13. For example, the turns of the first dipole winding 47 have the following configuration: +100, +100, +41, −41, −100, −100, −41, +41, where the sign specifies the orientation of the turn and the numeral specifies the number of turns at the respective support 13, starting with the support 13 depicted top centre and proceeding clockwise.

The second dipole winding 49 has a multiplicity of turns at each support 13. The number of turns of the second dipole winding 49 at a respective support 13 is represented schematically by the thickness of the second dipole winding 49 at the respective support 13. The orientation of the turns of the second dipole winding 49 at a respective support 13 is represented schematically by an arrow (located to the outside in the radial direction R) at the respective support 13. For example, the turns of the second dipole winding 49 have the following configuration: −41, +41, +100, +100, +41, −41, −100, −100, where the sign specifies the orientation of the turn and the numeral specifies the number of turns at the respective support 13, starting with the support 13 depicted top centre and proceeding clockwise. Using the dipole windings 47 and 49, it is possible to create a magnetic dipole field, rotatable as desired, in the propagation region 4.

Such dipole fields can also be created with different configurations of the number of turns and orientations of the turns. The present embodiment only shows an embodiment for implementing a dipole winding.

A further multipole element 1A according to an embodiment of the disclosure is described below with reference to FIG. 11. In contrast to the multipole element 1 described above, the multipole element 1A is an electric-magnetic multipole element. This means that the multipole element 1A is configured to create a magnetic multipole field and an electric multipole field. In this context, the same number of magnetic north poles and magnetic south poles of the magnetic multipole field are created; and the same number of positive poles and negative poles of the electric multipole field are created. Moreover, the number of poles of the magnetic multipole field equals the number of poles of the electric multipole field. In particular, the magnetic multipole field and the electric multipole field are created such that they are superimposed on one another in space.

A further difference to the multipole element 1, which is an octupole element, is that the multipole element 1A is a quadrupole element having four pole pieces 19 and four supports 13. Four is the maximum number of electric field poles, and four is the maximum number of magnetic field poles. The multipole element 1A may have a different number of poles, pole pieces 19 and supports 13 in further embodiments, for example six, eight or more.

The tube 3 has a low magnetic conductivity and is magnetically insulating in particular. Further, the tube 3 is electrically insulating in order to electrically insulate the pole pieces 19 and the supports 13 from one another. Moreover, the pole pieces 19 are electrically conductive. As a result, a high electric potential can be applied to the pole pieces 19, while the supports 13 are kept at earth potential. Consequently, the pole pieces 19 in the electric-magnetic multipole element 1A also serve as electrodes for creating the electric multipole field. However, this also means that the pole pieces 19 are retained in electrically insulated fashion in the mount 27 of the multipole element 1A; in this case, the material of the mount 27 is electrically nonconductive (at least in part).

The wall thickness TR of the tube 3 can be sufficiently large to maintain an electrical insulation of the pole pieces 19 vis-à-vis the supports 13 even in the presence of (in terms of absolute value) a high electrical potential difference therebetween. For example, the wall thickness TR of the tube 3 can be dimensioned such that the tube 3 has a breakdown voltage of at least 20 kV. In this case, the breakdown voltage denotes the smallest difference in terms of absolute value between the electric potential of the pole pieces 19 and the electric potential of the supports 13 at which the electrical insulation of the tube 3 fails.

To apply externally created electric potentials to the pole pieces 19, the multipole element 1A also comprises a plurality of first electrical lines 29, which electrically connect the pole pieces 19 to electrical connectors 31 in the external space assembly 7. Two first electrical lines 29 are depicted by way of example in FIG. 11. A region 33 of the tube 3 is emphasized by hatching in FIG. 11. The region 33 of the tube 3 adjoins the pole pieces 19 and the supports 13 in the radial direction R. In other words, the region 33 of the tube 3 is a region opposite the pole pieces 19 and the supports 13 in the radial direction R. In the region 33, the tube 3 has no opening (for a vacuum feedthrough) which passes through the tube 3 and the support 13 and the circumferential pole piece 11 in the radial direction R. In contrast to the prior art, which provides for an opening in the region 33 and consequently involves a vacuum seal, the configuration of the present embodiment does not require an opening in the region 33, facilitating the construction of the tube 3. By contrast, the tube 3 comprises a vacuum feedthrough 37 away from the region 33, the vacuum feedthrough maintaining the vacuum in the vacuum space in the radial direction R. The first electrical lines 29 pass through the tube 3 by way of the vacuum feedthrough 37. That is to say, the first electrical lines 29 pass through the tube 3 in the radial direction R outside of the region 33. Alternatively, the first lines 29 can be guided through the upper opening 6a in the tube 3 or the lower opening 6b in the tube 3. In a further alternative, some of the first electrical lines 29 can be guided through the vacuum feedthrough 37 outside of the region 33 and other first electrical lines 29 can be guided through the upper opening 6a in the tube 3 or the lower opening 6b in the tube 3.

In the examples shown in FIGS. 2 and 11, the vacuum feedthrough 37 is at a position located between two pole pieces 19 in the circumferential direction U. A possible position of the vacuum feedthrough 37 in the longitudinal direction is depicted in FIG. 2. From there, it is easy to contact an adjacent pole piece 19. In addition or in an alternative, a vacuum feedthrough 37 can be arranged above or below a pole piece 19 in the longitudinal direction. The number of vacuum feedthroughs 37 is not limited to one. That is to say, the multipole element 1A may comprise a plurality of vacuum feedthroughs 37 for guiding the first lines 29 therethrough.

In the example shown in FIG. 11, the multipole element 1A comprises the two first lines 29, which are electrically connected to two different pole pieces 19. In order to also be able to apply an external electric potential to the two other pole pieces 19 of the multipole element 1A, the multipole element 1A also comprises a plurality of second electrical lines 35 which electrically interconnect at least some of the pole pieces 19 in groups. Specifically, the multipole element 1A comprises a second electrical line 35 which electrically connects the pole piece 19 arranged at the top in FIG. 11 to the pole piece opposite thereto across the central axis 5 (i.e. the pole piece 19 arranged at the bottom in FIG. 11). Moreover, the multipole element 1A comprises a further second electrical line 35 which electrically connects the pole piece 19 arranged to the right in FIG. 11 to the pole piece opposite thereto across the central axis 5 (i.e. the pole piece 19 arranged to the left in FIG. 11). Hence, each pair of pole pieces 19 opposite one another across the central axis 5 are directly electrically connected to one another. In this example, each pair of pole pieces 19 opposite one another across the central axis 5 forms a group within the sense of the electrical connection “in groups”. Such a configuration reduces a negative influence of unwanted fluctuations in the external electric potentials. Like in the example of FIG. 11, the second lines 35 can be parts of the vacuum space assembly. Alternatively, the second lines 35 can be parts of the external space assembly. However, it is also possible within the scope of a further embodiment that the pole pieces 19 are individually supplied with externally created electric potentials via the first electrical lines 29.

During operation, the coils 17, the supports 13 and the circumferential pole piece 11 can remain at earth potential, whereas the pole pieces 19 are at a high voltage. An electrical potential difference between a mean electric potential of the pole pieces 19 (i.e. an (arithmetic) mean value of the electric potentials of the pole pieces 19) and an electric potential of the supports 13 is (in terms of absolute value) for example at least 2 kV, such as at least 6 kV. For the purpose of creating an electric quadrupole field with regard to the multipole element 1A shown in FIG. 11, an electric potential of for example +2 kV, +4 kV, +2 kV and +4 kV (when counting in the circumferential direction) can be applied to the four pole pieces 19, while an electric potential of 0 V (i.e. earth potential or ground potential) is applied to the supports 13. As a result, the mean electric potential of the pole pieces 19 has a value of +3 kV, and an electrical potential difference between the mean electric potential of the pole pieces 19 and an electric potential of the supports 13 is also +3 kV.

Further or alternatively, an electrical potential difference between a mean electric potential of the pole pieces 19 (i.e. an (arithmetic) mean value of the electric potentials of the pole pieces 19) and an electric potential of the circumferential pole piece 11 is (in terms of absolute value) at least 2 kV, such as at least 6 kV. Further or alternatively, a maximum electrical potential difference between electric potentials of adjacent pole pieces 19 is (in terms of absolute value) at least 200 V, such as at least 1 kV. Further or alternatively, an electrical potential difference between a mean electric potential of the pole pieces 19 (i.e. an (arithmetic) mean value of the electric potentials of the pole pieces 19) and an earth potential is (in terms of absolute value) at least 2 kV, such as at least 6 kV. The earth potential can also be referred to as ground potential.

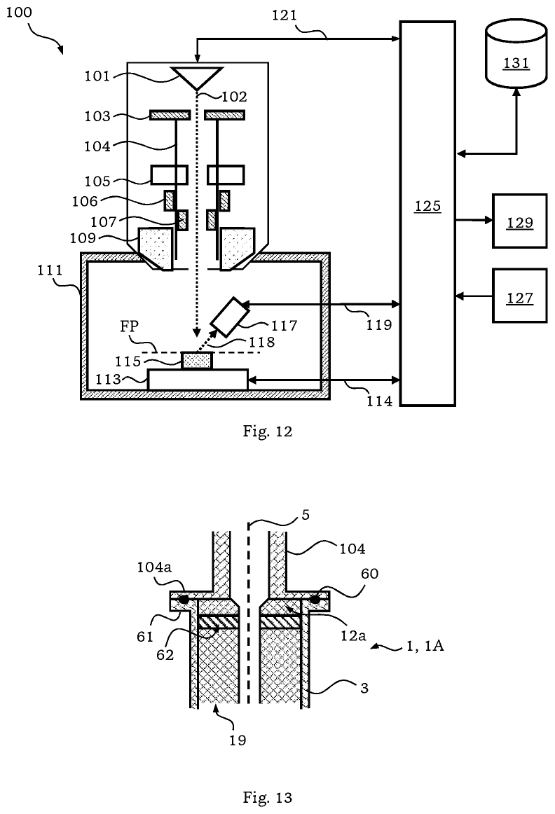

An exemplary particle beam system 100 is described below with reference to FIG. 12. For example, the particle beam system 100 can be an electron beam microscope or a processing system having a focused ion beam.

For example, the particle beam system 100 comprises a particle beam column. The particle beam column comprises a particle source 101 for providing charged particles of a particle beam 102, for example electrons or ions; an acceleration electrode 103 for accelerating the particles in the particle beam 102; a beam tube 104, through which the particle beam 102 runs within the particle beam system 100; an image error corrector 105, which comprises at least one of the multipole elements 1, 1A described herein; deflection coils 106 and/or deflection electrodes 107 for deflecting the particle beam 102; and an objective lens 109 for focusing the particle beam 102 on a focal plane FP. The particle beam column comprises a housing in which the aforementioned components are accommodated. For example, the beam tube 104 can extend from the acceleration electrode 103 to the objective lens 109. The beam tube 104 may be interrupted, for example by the image error corrector 105 (the multipole element 1). Some components of the particle beam system 100, for example the image error corrector 105 (the multipole element 1) and the deflection electrodes 107, may be arranged, in full or in part, within the beam tube 104.

The particle beam system 100 also comprises a vacuum chamber 111, in which a sample stage 113 is arranged. The sample stage 113 is configured to carry a sample 115. The sample stage 113 may be configured to displace and rotate the sample 115.

The particle beam system 100 also comprises a detector 117 for detecting interaction products 118 created by the interaction of the particle beam 102 with the sample 115. Interaction products can be for example: secondary electrons, backscattered electrons, secondary ions, backscattered ions, light, radiation, etc.

The particle beam system 100 also comprises a controller 125 for control and data processing. The controller 125 controls the particle source 101, the acceleration electrode 103, the image error corrector 105, the deflection electrodes 107 and the objective lens 109 via a communications line 121. The controller 125 controls the sample stage 113 via a communications line 114. The controller 125 controls the detector 117 and receives data from the detector 117 via a communications line 119. An input device 127 is connected to the controller 125 in order to receive inputs from a user or a data medium. An output device 129 is connected to the controller 125 in order to output outputs from the controller 125 to a user or a data medium. The controller 125 is connected to a data memory 131 for storing data.

The particle beam system 100 also comprises one or more current sources and/or one or more voltage sources, which are not depicted in the figures. The current sources and voltage sources are configured to supply the components of the particle beam system 100, in particular electrodes for creating electric fields and coils for creating magnetic fields, with suitable voltages and electric currents. The current sources and voltage sources are controlled by the controller 125.

The beam tube 104 can be at a high voltage during operation. In particular, the same high voltage as applied to the pole pieces 19 can also be applied to the beam tube 104. For example, this means that the mean electric potential of the pole pieces 19 and the electric potential of the beam tube 104 are (virtually) the same. For example, a difference between the mean electric potential of the pole pieces 19 and the electric potential of the beam tube 104 is (in terms of absolute value) no more than 500 V, such as no more than 100 V. For example, an electrical potential difference between the beam tube 104 and the sample 115 is (in terms of absolute value) at least 2 kV or at least 6 kV. Moreover, a difference between the mean electric potential of the pole pieces 19 and the electric potential of the sample 115 can be (in terms of absolute value) at least 2 kV or at least 6 kV.

The housing of the particle beam column, the vacuum chamber 111, the sample 115 or a power supply of the particle beam system 100 can be at earth potential and/or be earthed.

FIG. 13 shows a schematic cross-sectional view at a connecting point between the beam tube 104 and a multipole element 1 according to an embodiment that differs from the embodiment in FIG. 2. FIG. 13 shows only an upper portion of some of the components of the multipole element 1, specifically two pole pieces 19 arranged symmetrically about the central axis 5, the tube 3 and the upper termination pole piece 12a. The lower portion of the multipole element 1 can be formed similarly and can be connected to a lower portion of the beam tube 104.

FIG. 13 serves to explain an option for a vacuum-tight connection between the beam tube 104 and the multipole element 1. The beam tube 104 comprises an end portion 104a which provides a flange. The tube 3 comprises an end portion 61 which provides a flange that fits to the flange of the end portion 104a. A seal 60 sealing the beam tube 104 and the tube 3 is arranged between the beam tube 104 and the tube 3, more precisely between the end portion 104a and the end portion 61. For example, the seal 60 is an O-ring.

For example, a high voltage of +8 kV vis-à-vis earth potential is applied to the beam tube 104. The upper termination pole piece 12a is in contact with the beam tube 104.

Therefore, the high voltage of +8 kV vis-à-vis earth potential is also applied to the upper termination pole piece 12a. An electrical insulation 62 which electrically insulates the upper termination pole piece 12a and the pole pieces 19 from one another is arranged between the upper termination pole piece 12a and the pole pieces 19. As a result, electric potentials that are different from one another and different from the electric potential of the upper termination pole piece 12a can be applied to the pole pieces 19. The electrical insulation 62 can be formed by an electrically insulating solid material or an empty space (vacuum).

### LIST OF REFERENCE SIGNS

1, 1A Multipole element;
3 Tube;
4 Propagation region;
5 Central axis;
6a, 6b Opening in the tube at the central axis;
7 External space assembly;
9 Vacuum space assembly;
11 Circumferential pole piece;
12a Upper termination pole piece;
12b Lower termination pole piece;
13 Supports;
15 Outer wall surface of the tube;
16 Inner wall surface of the tube;
17 Coils;
19, 19A, 19B, 19C, 19D Pole pieces;
21, 22 Lateral surfaces of a pole piece;
23 Inner surface of a pole piece;
25 Outer surface of a pole piece;
27 Mount;
29 First electrical line;
31 Electrical connectors;
33 Region of the tube between pole piece and support;
35 Second electrical line;
37 Vacuum feedthrough;
41 Octupole winding;
42 Connectors of the octupole winding;
43 First quadrupole winding;
44 Connectors of the first quadrupole winding;
45 Second quadrupole winding;
46 Connectors of the second quadrupole winding;
47, 49 Dipole winding;
48, 50 Connectors of the dipole windings;
60 Seal;
61 End portion;
62 Insulation;
100 Particle beam system;
101 Particle source;
102 Particle beam;
103 Acceleration electrode;
104 Beam tube;
104a End portion;
105 Image error corrector;
106 Deflection coils;
107 Deflection electrodes;
109 Objective lens;
111 Vacuum chamber;
113 Sample stage;
114 Communications link;
115 Sample;
117 Detector;
118 Interaction products;
119 Communications link;
121 Communications link;
125 Controller;
127 Input device;
129 Output device;
131 Data memory;
D1 Distance in the radial direction between pole piece and tube;
DR Internal diameter of the tube;
FP Focal plane;
h1 First half-line;
h2 Second half-line;
h3 Third half-line;
h4 Fourth half-line;
k1 First edge;
k2 Second edge;
k3 Third edge;
k4 Fourth edge;
L Length of a pole piece in the radial direction;
R Radial direction;
R0 Smallest distance between central axis and pole piece;
S1, S2 Point of intersection;
TR Wall thickness of the tube in the radial direction;
TP Thickness of the pole piece in the circumferential direction;
U Circumferential direction;
α Inner coverage angle;
β Outer coverage angle;
Φ Coverage angle.

What is claimed is:

1. A multipole element, comprising:
a tube surrounding a central axis of the multipole element; and
an external space assembly outside the tube relative to a radial direction perpendicular to the central axis, the external space assembly outside a vacuum space assembly within the tube relative to the radial direction,
wherein the external space assembly comprises:
a magnetically conductive circumferential pole piece surrounding the tube in a circumferential direction, the circumferential direction being perpendicular to the central axis and to the radial direction;
a plurality of magnetically conductive supports distributed around the central axis and extending from the circumferential pole piece against the radial direction up to an outer wall surface of the tube; and
a plurality of coils,
wherein the vacuum space assembly comprises a plurality of magnetically conductive pole pieces distributed around the central axis and extending from the tube against the radial direction, and
wherein the multipole element configured so that, during use:
an electrical potential difference between a mean electric potential of the pole pieces and an electric potential of the supports is at least 2 kV; and/or
an electrical potential difference between a mean electric potential of the pole pieces and an electric potential of the circumferential pole piece is at least 2 kV.

2. The multipole element of claim 1, wherein a distance in the radial direction between the tube and any one of the supports is at least zero.

3. The multipole element of claim 1, wherein a distance in the radial direction between the tube and any one of the supports is less than 20% of an internal diameter of the tube in the radial direction, and/or a distance in the radial direction between the tube and any one of the supports is less than 5 mm.

4. The multipole element of claim 1, wherein a distance in the radial direction between the tube and any one of the supports is at least zero.

5. The multipole element of claim 1, wherein a distance in the radial direction between any one of the pole pieces and the tube is less than 20% of an internal diameter of the tube in the radial direction, and/or a distance in the radial direction between any one of the pole pieces and the tube is less than 5 mm.

6. The multipole element of claim 1, wherein a wall thickness of the tube in the radial direction is greater than zero.

7. The multipole element of claim 1, wherein a wall thickness of the tube in the radial direction is less than 20% of an internal diameter of the tube in the radial direction, and/or a wall thickness of the tube in the radial direction is less than 5 mm.

8. The multipole element of claim 1, wherein the supports do not pass through the tube in the radial direction, and the pole pieces do not pass through the tube in the radial direction.

9. The multipole element of claim 1, wherein the tube is configured to provide a vacuum separation in the radial direction between the vacuum space assembly and the external space assembly.

10. The multipole element of claim 1, wherein the tube is magnetically nonconductive.

11. The multipole element of claim 1, wherein:
each pole piece is configured such that its an inner coverage angle and its an outer coverage angle have different values from one another;
a radius-dependent coverage angle specifies an acute angle between a first half-line and a second half-line;
the first half-line lies in a cross-sectional plane oriented perpendicularly to the central axis, emanates from the central axis, and runs through a first point of intersection;
the second half-line lies in the cross-sectional plane, emanates from the central axis, and runs through a second point of intersection;
the first point of intersection and the second point of intersection are points of intersection of the surface of the respective pole piece with a circle which lies in the cross-sectional plane, has a radius r, and has its center on the central axis;
the inner coverage angle is defined as the largest radius-dependent coverage angle in a range R0≤r<R0+20% L;
the outer coverage angle is defined as the largest radius-dependent coverage angle in a range DR/2−20% L<r≤DR/2;
R0 is the smallest distance in the radial direction between the surface of the respective pole piece and the central axis;
DR is the internal diameter of the tube; and
L is the maximum length of the respective pole piece in the radial direction.

12. The multipole element of claim 11, wherein:
a sector width is defined as the ratio of 360° to the number of pole pieces; and
each pole piece is shaped such that at least one of the following holds:
its inner coverage angle is greater than its outer coverage angle;
a difference between the inner coverage angle and the outer coverage angle is at least 10% of the sector width;
a ratio of the inner coverage angle to the sector width has a value ranging from 75% to 95%; and
a ratio of the outer coverage angle to the sector width has a value ranging from 35% to 75%.

13. The multipole element of claim 11, wherein:
each pole piece is shaped such that a mid coverage angle of pole piece is both smaller than the inner coverage angle of the pole piece and smaller than the outer coverage angle of the pole piece (19); and
the mid coverage angle is defined as the smallest radius-dependent coverage angle in a range R0+20% L<r<DR/2−20% L.

14. The multipole element of claim 1, wherein:
each pole piece is shaped such that a mid coverage angle of the pole piece is both smaller than an inner coverage angle of the pole piece and smaller than an outer coverage angle of the pole piece;
a radius-dependent coverage angle specifies an acute angle between a first half-line and a second half-line;
the first half-line lies in a cross-sectional plane oriented perpendicularly to the central axis, emanates from the central axis, and runs through a first point of intersection;
the second half-line lies in the cross-sectional plane, emanates from the central axis, and runs through a second point of intersection;
the first point of intersection and the second point of intersection are points of intersection of the surface of the respective pole piece with a circle which lies in the cross-sectional plane, has the radius r and has its centre on the central axis;
the inner coverage angle is defined as the largest radius-dependent coverage angle in a range R0≤r<R0+20% L;
the outer coverage angle is defined as the largest radius-dependent coverage angle in a range DR/2−20% L<r≤DR/2;
the mid coverage angle is defined as the smallest radius-dependent coverage angle in a range R0+20% L<r<DR/2−20% L;
R0 is the smallest distance in the radial direction between the surface of the respective pole piece and the central axis;
DR is the internal diameter of the tube; and
L is the maximum length of the respective pole piece in the radial direction.

15. The multipole element of claim 1, wherein:
each pole piece comprises two lateral surfaces, each of which faces an adjacent pole piece of the pole pieces in the circumferential direction; and
the lateral surfaces of the pole pieces are curved or bent.

16. The multipole element of claim 1, wherein the vacuum space assembly further comprises a mount configured to retain the pole pieces.

17. The multipole element of claim 16, wherein the tube at least partially comprises the mount.

18. The multipole element of claim 1, wherein:
the tube is electrically insulating;
the pole pieces are electrically conductive; and
the multipole element further comprises a plurality of first electrical lines electrically connecting the pole pieces to electrical connectors in the external space assembly.

19. The multipole element of claim 18, wherein at least some of the plurality of first electrical lines extend through an opening in the tube located on the central axis.

20. The multipole element of claim 18, wherein the plurality of first electrical lines pass through the tube in the radial direction outside a region of the tube adjoining the pole pieces and the supports in the radial direction.

21. The multipole element of claim 18, further comprising a plurality of second electrical lines electrically interconnecting at least some of the pole pieces in groups.

22. The multipole element of claim 21, wherein each second electrical line electrically interconnects a pair of pole pieces lying opposite one another across the central axis.

23. The multipole element of claim 1, wherein a region of the tube adjoining the pole pieces and the supports in the radial direction contains no opening extending through the tube in the radial direction.

24. The multipole element of claim 1, wherein the multipole element is configured so that, during use, an electrical potential difference between a mean electric potential of the pole pieces and an earth potential is at least 2 kV.

25. The multipole element of claim 1, wherein:
the multipole element is a quadrupole element comprising four pole pieces and four supports;
the coils comprise at least one winding from a group of windings; and
the group of windings comprises:
a quadrupole field winding configured to create a magnetic quadrupole field; and
a plurality of separated dipole field windings configured to create magnetic dipole fields.

26. The multipole element of claim 1, wherein:
the multipole element is an octupole element comprising eight pole pieces and eight supports;
the coils comprise at least one winding from a group of windings; and
the group of windings comprises:
an octupole field winding configured to create a magnetic octupole field;
a plurality of separated quadrupole field windings configured to create magnetic quadrupole fields; and
a plurality of separated dipole field windings configured to create magnetic dipole fields.

27. An image error corrector comprising a multipole element according to claim 1.

28. A particle beam system comprising a multiple element according to claim 1.

29. The particle beam system of claim 28, further comprising:
a beam tube; and
a voltage source configured to create an electrical potential difference of at least 2 kV between the beam tube and a sample.
